(19) United States
(12) Patent Application Publication
(10) Pub. No.: US 2025/0031527 A1
(43) Pub. Date: Jan. 23, 2025

(54) Display Panel and Manufacturing Method Thereof

(71) Applicant: HKC CORPORATION LIMITED, Shenzhen (CN)

(72) Inventors: Hongchen LI, Shenzhen (CN); Haijiang YUAN, Shenzhen (CN)

(73) Assignee: HKC CORPORATION LIMITED, Shenzhen (CN)

(21) Appl. No.: 18/764,470

(22) Filed: Jul. 5, 2024

(30) Foreign Application Priority Data
Jul. 17, 2023 (CN) 202310879072.7

(51) Int. Cl. H10K 59/122; H10K 59/12; H10K 59/80

(52) U.S. Cl. CPC H10K 59/122; H10K 59/1201; H10K 59/873

(57) ABSTRACT

The present disclosure relates to a display panel and a manufacturing method thereof. The display panel includes a boundary isolation layer located on a side of a pixel defining layer away from an array substrate, a second electrode layer corresponding to two adjacent sub-pixels is disconnected at an edge of the boundary isolation layer, the boundary isolation layer includes a conductive part and a shielding part located on a side of the conductive part away from the array substrate, and an orthographic projection of the shielding part on the array substrate covers an orthographic projection of the conductive part on the array substrate, in which an end of the conductive part away from the shielding part is embedded in the pixel defining layer to prevent water and oxygen from infiltrating from the pixel defining layer into the light-emitting functional layer.

### CROSS-REFERENCE TO RELATED APPLICATIONS

The present disclosure claims all the benefits of the Chinese patent application No. 202310879072.7, filed on Jul. 17, 2023 before the China National Intellectual Property Administration of the People's Republic of China, entitled “Display Panel And Manufacturing Method Thereof”, which is explicitly incorporated herein by reference in their entirety.

### FIELD

The present disclosure relates to the field of display technology, particularly to a display panel and a manufacturing method thereof.

### BACKGROUND

With increase of a size of an organic light-emitting diode (OLED) display panel, a cathode layer area of a light-emitting element also increases. A cathode layer of a top-emitting OLED display panel needs to meet requirements of light transmittance and cannot be too thick. Such a large-area cathode layer will certainly lead to drop of in-plane voltage (IR-Drop), which affects brightness uniformity of a display screen.

Therefore, a boundary isolation layer is usually set on a pixel defining layer in the related art to overlap the cathode layer, so as to reduce overall resistance of the cathode layer. The boundary isolation layer has a combined structure of metal (conductive layer) and an inorganic silicon-containing material and is prepared by whole-layer evaporation and photoetching. However, a material of the pixel defining layer is generally soluble polytetrafluoroethylene. In the process of photoetching, the whole substrate is exposed to a high humidity environment, and water and oxygen easily infiltrate into a light-emitting functional layer through the pixel defining layer, resulting in failure of the light-emitting functional layer.

### SUMMARY

The present disclosure aims to provide a display panel and a manufacturing method thereof. The display panel can reduce cathode signal transmission resistance and eliminate device crosstalk between light-emitting sub-pixels, and meanwhile can reduce water vapor infiltration in a photoetching process and improve a product yield.

In a first aspect, an embodiment of the present disclosure provides a display panel comprising a plurality of pixel units arranged in an array, the pixel unit comprising a plurality of sub-pixels, the display panel comprising an array substrate, and a pixel defining layer, a light-emitting functional layer and an encapsulation layer sequentially formed on the array substrate, in which the array substrate is formed with a plurality of first electrodes arranged in an array, and the pixel defining layer comprises a plurality of pixel openings which expose at least part of the first electrode; the light-emitting functional layer comprises a light-emitting structure on the first electrode and a second electrode layer on the light-emitting structure, wherein the display panel further comprises a boundary isolation layer located on a side of the pixel defining layer away from the array substrate, the second electrode layer corresponding to two adjacent sub-pixels is disconnected at an edge of the boundary isolation layer, the boundary isolation layer comprises a conductive part and a shielding part located on a side of the conductive part away from the array substrate, and an orthographic projection of the shielding part on the array substrate covers an orthographic projection of the conductive part on the array substrate; and an end of the conductive part away from the shielding part is embedded in the pixel defining layer to prevent water and oxygen from infiltrating from the pixel defining layer into the light-emitting functional layer.

In some embodiments, the conductive part comprises a tip part and a support part which are sequentially arranged along a light-emitting direction, the tip part is embedded in the pixel defining layer, and the support part is located between the tip part and the shielding part; the tip part is tapered away from the light-emitting direction, and the support part is tapered along the light-emitting direction.

In some embodiments, a minimum width dimension of the tip part is greater than 0.2 μm, a total thickness of the conductive part is 2 μm to 4 μm, and a thickness of the support part is 0.8 μm to 1.5 μm.

In some embodiments, the pixel defining layer is correspondingly provided with a groove that accommodates the conductive part.

In some embodiments, the conductive part is produced by printing.

In some embodiments, a material of the shielding part is an inorganic silicon-containing material.

In some embodiments, a material of the conductive part comprises any one of nano silver paste, nano copper conductive ink and conductive aluminum paste.

In some embodiments, the boundary isolation layer is provided on at least one of the sub-pixels in at least one of the pixel units.

In some embodiments, the encapsulation layer comprises a first inorganic layer, an organic layer and a second inorganic layer that are sequentially arranged in a direction away from the array substrate, in which the first inorganic layer and the second inorganic layer cover the light-emitting functional layer and the boundary isolation layer, and the organic layer has high elasticity and is sandwiched between the first inorganic layer and the second inorganic layer.

In a second aspect, an embodiment of the present disclosure further provides a manufacturing method of a display panel, comprising: providing an array substrate formed with a plurality of first electrodes arranged in an array; forming a patterned pixel defining layer on the array substrate, wherein the pixel defining layer comprises a plurality of pixel openings and a plurality of grooves, and the pixel opening exposes at least part of the first electrode; printing a whole conductive layer on the pixel defining layer, wherein the conductive layer covers a plurality of the pixel openings and a plurality of the grooves; forming a whole shielding layer on the conductive layer; patterning the shielding layer and the conductive layer by photoetching to form a boundary isolation layer, wherein the boundary isolation layer comprises a conductive part and a shielding part located on a side of the conductive part away from the array substrate, an orthographic projection of the shielding part on the array substrate covers an orthographic projection of the conductive part on the array substrate, and an end of the conductive part away from the shielding part is embedded in the groove of the pixel defining layer; and forming a light-emitting functional layer and an encapsulation layer on the pixel defining layer and the boundary isolation layer, wherein the light-emitting functional layer comprises a light-emitting structure on the first electrode and a second electrode layer on the light-emitting structure, the second electrode layer corresponding to two adjacent sub-pixels is disconnected at an edge of the boundary isolation layer, and the conductive part is configured to prevent water and oxygen from infiltrating from the pixel defining layer into the light-emitting functional layer.

In some embodiments, the display panel comprises a display area and a frame area located on a periphery of the display area, and printing the whole conductive layer on the pixel defining layer comprises: printing the whole conductive layer corresponding to the display area on the pixel defining layer.

In some embodiments, the conductive part comprises a tip part and a support part which are sequentially arranged along a light-emitting direction, the tip part is embedded in the pixel defining layer, and the support part is located between the tip part and the shielding part; the tip part is tapered away from the light-emitting direction, and the support part is tapered along the light-emitting direction.

In some embodiments, a minimum width dimension of the tip part is greater than 0.2 μm, a total thickness of the conductive part is 2 μm to 4 μm, and a thickness of the support part is 0.8 μm to 1.5 μm.

In some embodiments, the pixel unit comprises a first sub-pixel, a second sub-pixel and a third sub-pixel with different colors, and forming the light-emitting functional layer and the encapsulation layer on the pixel defining layer and the boundary isolation layer comprises: evaporating a whole first color light-emitting layer on the pixel defining layer and the boundary isolation layer; forming a whole encapsulation layer on the first color light-emitting layer; removing a light-emitting layer and the encapsulation layer except the first sub-pixel with the first color by photoetching; evaporating a whole second color light-emitting layer on the pixel defining layer and the boundary isolation layer; forming a whole encapsulation layer on the second color light-emitting layer; removing a light-emitting layer and the encapsulation layer except the second sub-pixel with the second color by photoetching; evaporating a whole third color light-emitting layer on the pixel defining layer and the boundary isolation layer; forming a whole encapsulation layer on the third color light-emitting layer; and removing a light-emitting layer and the encapsulation layer except the third sub-pixel with the third color by photoetching.

In the display panel and the manufacturing method thereof provided by embodiments of the present disclosure, the display panel comprises a plurality of pixel units arranged in an array, the pixel unit comprising a plurality of sub-pixels, the display panel comprising an array substrate, and a pixel defining layer, a light-emitting functional layer and an encapsulation layer sequentially formed on the array substrate, in which the array substrate is formed with a plurality of first electrodes arranged in an array, and the pixel defining layer comprises a plurality of pixel openings which expose at least part of the first electrode; the light-emitting functional layer comprises a light-emitting structure on the first electrode and a second electrode layer on the light-emitting structure, wherein the display panel further comprises a boundary isolation layer located on a side of the pixel defining layer away from the array substrate, the second electrode layer corresponding to two adjacent sub-pixels is disconnected at an edge of the boundary isolation layer, the boundary isolation layer comprises a conductive part and a shielding part located on a side of the conductive part away from the array substrate, and an orthographic projection of the shielding part on the array substrate covers an orthographic projection of the conductive part on the array substrate; and an end of the conductive part away from the shielding part is embedded in the pixel defining layer to prevent water and oxygen from infiltrating from the pixel defining layer into the light-emitting functional layer. By embedding the conductive part of the boundary isolation layer into the pixel defining layer, water and oxygen can be prevented from infiltrating from the pixel defining layer into the light-emitting functional layer during the manufacturing process, which can reduce cathode signal transmission resistance and eliminate device crosstalk between light-emitting sub-pixels, and meanwhile can reduce water vapor infiltration in a photoetching process and improve a product yield.

### BRIEF DESCRIPTION OF THE DRAWINGS

Features, advantages, and technical effects of exemplary embodiments of the present disclosure will be described below with reference to the accompanying drawings. In the drawings, the same components bear the same reference numerals. The drawings are not drawn to actual scale and are used merely to indicate relative positional relationships. Some parts are drawn exaggeratedly in layer thicknesses to facilitate understanding, and the layer thicknesses in the drawings do not represent actual layer thicknesses.

FIG. 1 shows a cross-sectional structure diagram of a display panel provided by an embodiment of the present disclosure;

FIG. 2 shows an enlarged structure diagram of area B in FIG. 1;

FIG. 3 shows a flowchart of a manufacturing method of a display panel provided by an embodiment of the present disclosure; and

FIG. 4 shows a structural diagram of an encapsulation layer of a display panel provided by an embodiment of the present disclosure;

FIG. 5 shows a schematic diagram of a display panel provided by an embodiment of the present disclosure; and

FIG. 6 shows a diagram of a pixel unit of a display panel provided by an embodiment of the present disclosure.

### DESCRIPTION OF REFERENCE NUMERALS

1. array substrate; 11. first electrode; 2. pixel defining layer; 21. pixel opening; 22. groove; 3. light-emitting functional layer; 31. light-emitting structure; 32. second electrode layer; 4. boundary isolation layer; 41. conductive part; 411. tip part; 412. support part; 42. shielding part; 5. encapsulation layer; 51. first inorganic layer; 52. organic layer; 53. second inorganic layer; D. display area; F. frame area; U. pixel unit; R. first sub-pixel; G. second sub-pixel; B. third sub-pixel

### DETAILED DESCRIPTION

Features and exemplary embodiments of various aspects of the present disclosure will be described in detail below. In the following detailed description, numerous specific details are set forth in order to provide a thorough understanding of the present disclosure. However, it will be apparent to a person skilled in the art that the present disclosure may be implemented without some of these specific details. The following description of embodiments is merely to provide a better understanding of the present disclosure by illustrating examples of the present disclosure. In the drawings and the description below, at least some of the well-known structures and technologies are not shown in order to avoid unnecessarily obscuring the present disclosure; and for clarity, the dimensions of an area structure may be exaggerated. Furthermore, features, structures, or characteristics to be described below may be combined in any suitable manner in one or more embodiments.

Orientation words appearing in the following description are only directions shown in the drawings, and are not intended to limit a specific structure of the present disclosure. In the description of the present disclosure, it should also be noted that unless otherwise clearly specified or limited, the terms “install” and “connect” should be broadly understood, such as fixed connection, detachable connection or integral connection; and direct connection or indirect connection. The specific meanings of the above terms in the disclosure may be understood based on specific circumstances by a person skilled in the art.

At present, there are usually three ways of mass production of a light-emitting device in an OLED display panel: first, using a fine metal mask as a mask to deposit three-color sub-pixels by an evaporation process; second, accurately printing sub-pixels in different positions by an ink-jet printing process; and third, forming a film on the whole surface by an evaporation process, and then etching a substrate after film formation by photoetching to separate sub-pixels of three colors. With the increasing popularity of large-size display panels, it has become trends in the industry to adopt the third method of combining evaporation and etching since sag of the metal mask is excessive in the first method. That is, firstly, a film is formed on the whole surface by the evaporation process, and with the help of a special structure of an evaporation source, a cathode end of the sub-pixel may overlap a boundary isolation layer, and then, the substrate after film formation is etched by photoetching to separate sub-pixels of three colors.

An embodiment provides a display panel and a manufacturing method thereof, which can reduce cathode signal transmission resistance and eliminate device crosstalk between light-emitting sub-pixels, and meanwhile can reduce water vapor infiltration in a photoetching process and improve a product yield.

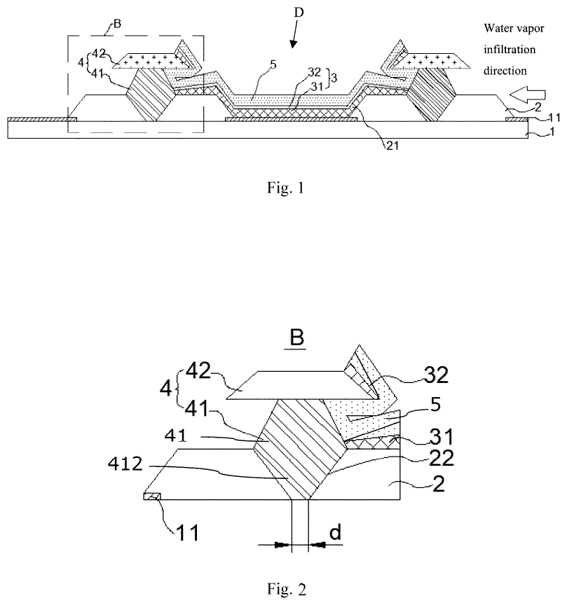

FIG. 1 shows a cross-sectional structure diagram of a display panel provided by an embodiment of the present disclosure; FIG. 2 shows an enlarged structure diagram of area B in FIG. 1; and FIG. 6 shows a diagram of a pixel unit of a display panel provided by an embodiment of the present disclosure.

As shown in FIG. 1, FIG. 2 and FIG. 6, a display panel provided by an embodiment of the present disclosure includes a plurality of pixel units U arranged in an array, the pixel unit U including a plurality of sub-pixels R, G and B, the display panel including an array substrate 1, and a pixel defining layer 2, a light-emitting functional layer 3 and an encapsulation layer 5 sequentially formed on the array substrate 1, wherein the array substrate 1 is formed with a plurality of first electrodes 11 arranged in an array, and the pixel defining layer 2 includes a plurality of pixel openings 21 which expose at least part of the first electrode 11; the light-emitting functional layer 3 includes a light-emitting structure 31 on the first electrode 11 and a second electrode layer 32 on the light-emitting structure 31.

The display panel further includes a boundary isolation layer 4 located on a side of the pixel defining layer 2 away from the array substrate 1, and the second electrode layer 32 corresponding to two adjacent sub-pixels is disconnected at an edge of the boundary isolation layer 4, the boundary isolation layer 4 includes a conductive part 41 and a shielding part 42 located on a side of the conductive part 41 away from the array substrate 1, and an orthographic projection of the shielding part 42 on the array substrate 1 covers an orthographic projection of the conductive part 41 on the array substrate 1; an end of the conductive part 41 away from the shielding part 42 is embedded in the pixel defining layer 2 to prevent water and oxygen from infiltrating from the pixel defining layer 2 into the light-emitting functional layer 3.

In this embodiment, the display panel has a top emission structure, the first electrode 11 is an anode, and the second electrode layer 32 is a cathode laid as a whole surface, wherein the second electrode layer 32 corresponding to two adjacent sub-pixels is disconnected at the edge of the boundary isolation layer 4, so that the edge of the boundary isolation layer 4 can overlap the conductive part 41 of the boundary isolation layer 4, and overall resistance of the second electrode layer 32 can be reduced with the boundary isolation layer 4.

In some embodiments, the boundary isolation layer 4 is provided on at least one sub-pixel of at least one pixel unit. The greater the number of the boundary isolation layers 4, the smaller the voltage drop of the overall resistance of the second electrode layer 32, which is conducive to improving brightness uniformity of the display panel.

In some embodiments, the shape of the sub-pixel is any one of a circle, an ellipse and a polygon, or a combination of at least two thereof. The polygon may be but not limited to a triangle, a trapezoid, a rectangle, a quadrilateral, a pentagon, a hexagon and the like. In the pixel unit, shapes of the sub-pixels may be the same or different depending on specific arrangement structure of the pixels.

As shown in FIG. 1, since an end of the conductive part 41 of the boundary isolation layer 4 away from the shielding part 42 can be embedded in the pixel defining layer 2, there is a close fit and no gap between the conductive part 41 and the pixel defining layer 2. Although exposed to a high humidity environment, the product can prevent water and oxygen from infiltrating from the pixel defining layer 2 into the light-emitting functional layer 3 during evaporation and photoetching of the light-emitting functional layer 3, thus improving the product yield.

In some embodiments, the conductive part 41 includes a tip part 411 and a support part 412 which are sequentially arranged along a light-emitting direction, the tip part 411 is embedded in the pixel defining layer 2, and the support part 412 is located between the tip part 411 and the shielding part 42, wherein the tip part 411 is tapered away from the light-emitting direction, and the support part 412 is tapered along the light-emitting direction.

The support part 412 is tapered along the light-emitting direction to support the shielding part 42. The tip part 411 is tapered away from the light-emitting direction, and the pixel defining layer 2 is correspondingly provided with a groove 22 that accommodates the conductive part 41, so that bonding tightness between the conductive part 41 and the pixel defining layer 2 can be improved, and water vapor infiltration in the photoetching process can be reduced.

In some embodiments, the minimum width dimension d of the tip part 411 is greater than 0.2 μm; the total thickness of the conductive part 41 is 2 μm to 4 μm, and the thickness of the support part 412 is 0.8 μm to 1.5 μm. Since the tip part 411 is tapered away from the light-emitting direction, the minimum width dimension d thereof is a dimension embedded in the bottom of the pixel defining layer 2.

In the related art, the conductive part 41 is produced by a film forming process of physical vapor deposition (PVD). Considering that the thickness of the conductive part 41 is large, generally greater than 1 μm, stress after film formation is too large, which easily leads to warping of a display panel. In order to overcome the stress, film formation by stages is usually chosen in the PVD process in the related art, and cooling time is increased to release the stress during the film formation process. However, the stages and cooling steps will double process time and greatly affect productivity release.

In this embodiment, the conductive part 41 is produced by printing, which may include but is not limited to screen printing, ink-jet printing, relief printing, and the like. Compared with strong electric field sputtering film formation of the PVD, the printing film formation method has less stress, material is cured by baking, temperature rises and falls uniformly, thermal stress has less impact, and a problem of warping of the display panel is improved.

The material of the conductive part 41 is mainly printable metal paste with good conductivity and fluidity. In some embodiments, the material of the conductive part 41 includes any one of nano silver paste, nano copper conductive ink and conductive aluminum paste. In addition, the material of the shielding part 42 is an inorganic silicon-containing material, such as a single substance or a mixture of multiple substances of SiON, SiN, SiO, and the like.

In some embodiments, the light-emitting functional layer 3 further includes a first common layer and a second common layer. The first common layer includes a hole injection layer (HIL) located on the first electrode 11 and a hole transport layer (HTL) located on a surface of the hole injection layer away from the array substrate 1. The second common layer includes an electron transport layer (ETL) located on a surface of the light-emitting structure 31 and an electron injection layer (EIL) located on a surface of the electron transport layer away from the light-emitting structure 31.

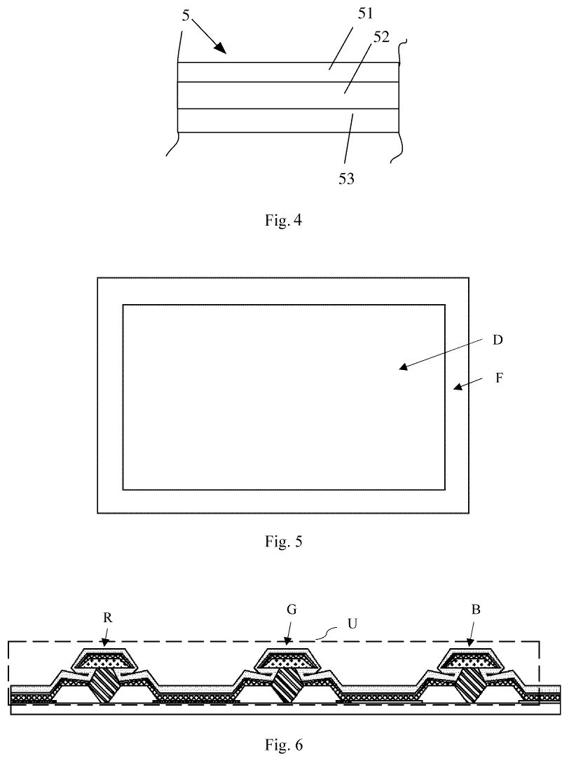

FIG. 4 shows a structural diagram of an encapsulation layer of a display panel provided by an embodiment of the present disclosure. As shown in FIG. 4, the encapsulation layer 5 includes a first inorganic layer 51, an organic layer 52, and a second inorganic layer 53 that are sequentially arranged in a direction away from the array substrate 1. The first inorganic layer 51 and the second inorganic layer 53 are both a transparent inorganic film layer, and materials thereof may include one or more of the following: Al₂O₃, TiO₂, ZrO₂, MgO, HFO₂, TazOs, Si₃N₄, AlN, SiN, SiNO, SiO, SiO₂, SiC, SiCNₓ, ITO, and IZO. These inorganic materials not only have good light transmission performance, but also have good water and oxygen barrier performance. The material of the organic layer is transparent organic conductive resin, specifically including transparent matrix resin, and conductive molecules and/or conductive ions. Specifically, the organic conductive resin may be a transparent conductive resin formed by completely dissolving organic acid doped polyaniline, crosslinking monomer, toluene, and the like; alternatively, the above transparent conductive resin added with conductive molecules such as polyaniline; alternatively, the above transparent conductive resin added with conductive ions such as nano antimony-doped SiO₂, and nano conductive ions such as nano indium tin oxide and nano silver.

The first inorganic layer 51 and the second inorganic layer 53 made of inorganic materials completely cover the light-emitting functional layer 3 and the boundary isolation layer 4, which can prevent water vapor from invading from the side and affecting electrical performance of the light-emitting functional layer 3. The patterned organic layer has high elasticity, and is sandwiched between the first inorganic layer 51 and the second inorganic layer 53, which can not only inhibit cracking of the inorganic films and release stress between the inorganic substances, but also improve flexibility of the whole encapsulation layer, thus realizing reliable flexible encapsulation.

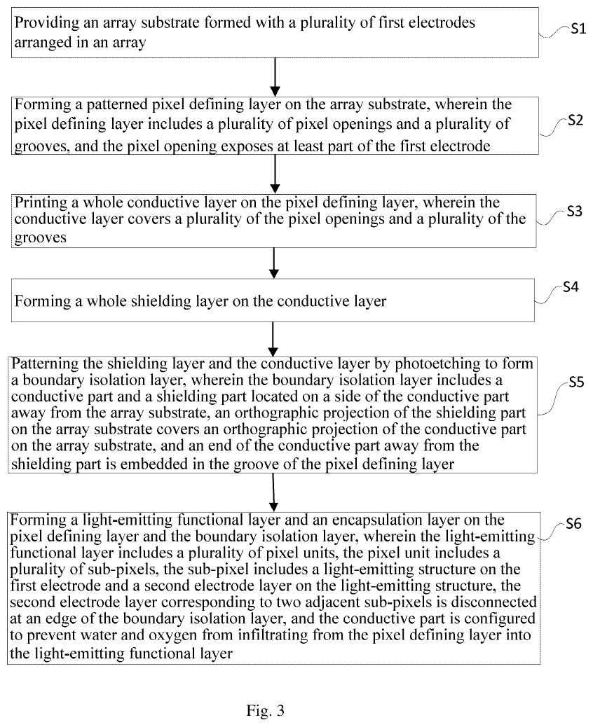

FIG. 3 shows a flowchart of a manufacturing method of a display panel provided by an embodiment of the present disclosure.

As shown in FIG. 3, an embodiment of the present disclosure further provides a manufacturing method of a display panel, which includes the following steps S1 to S6:

Step S1: providing an array substrate 1 formed with a plurality of first electrodes 11 arranged in an array;

Step S2: forming a patterned pixel defining layer 2 on the array substrate 1, wherein the pixel defining layer 2 includes a plurality of pixel openings 21 and a plurality of grooves 22, and the pixel opening 21 exposes at least part of the first electrode 11;

Step S3: printing a whole conductive layer (i.e. a position of the conductive part 41) on the pixel defining layer 2, wherein the conductive layer covers a plurality of the pixel openings 21 and a plurality of the grooves 22;

Step S4: forming a whole shielding layer (i.e., a position of the shielding part 42) on the conductive layer;

Step S5: patterning the shielding layer and the conductive layer by photoetching to form a boundary isolation layer 4, wherein the boundary isolation layer 4 includes a conductive part 41 and a shielding part 42 located on a side of the conductive part 41 away from the array substrate 1, an orthographic projection of the shielding part 42 on the array substrate 1 covers an orthographic projection of the conductive part 41 on the array substrate 1, and an end of the conductive part 41 away from the shielding part 42 is embedded in the groove 22 of the pixel defining layer 2; and

Step S6: forming a light-emitting functional layer 3 and an encapsulation layer 5 on the pixel defining layer 2 and the boundary isolation layer 4, wherein the light-emitting functional layer 3 includes a light-emitting structure 31 on the first electrode 11 and a second electrode layer 32 on the light-emitting structure 31, and the second electrode layer 32 corresponding to two adjacent sub-pixels is disconnected at an edge of the boundary isolation layer 4, and the conductive part 41 is configured to prevent water and oxygen from infiltrating from the pixel defining layer 2 into the light-emitting functional layer 3.

In some embodiments, as shown in FIG. 5, the display panel includes a display area D and a frame area F located on the periphery of the display area D, and printing the whole conductive layer on the pixel defining layer 2 includes:
printing the whole conductive layer corresponding to the display area D on the pixel defining layer 2.

During layout, a plurality of display panels are usually laid out on a large piece of glass. Due to low precision of the printing process, when the whole conductive layer is printed on the pixel defining layer 2 of a plurality of the display panels, only a whole display area of each display panel can be printed, and non-display areas such as a cutting area, a bonding area and a dummy area are not printed. After baking and curing, an exposure etching process is used to produce a shape that meets the specifications. This can save the material of the conductive layer and reduce the production cost.

In some embodiments, the conductive part 41 includes a tip part 411 and a support part 412 which are sequentially arranged along a light-emitting direction, the tip part 411 is embedded in the pixel defining layer 2, and the support part 412 is located between the tip part 411 and the shielding part 42, wherein the tip part 411 is tapered away from the light-emitting direction, and the support part 412 is tapered along the light-emitting direction. The support part 412 is tapered along the light-emitting direction to support the shielding part 42. The tip part 411 is tapered away from the light-emitting direction, and the pixel defining layer 2 is correspondingly provided with a groove 22 that accommodates the conductive part 41, so that bonding tightness between the conductive part 41 and the pixel defining layer 2 can be improved, and water vapor infiltration in the photoetching process can be reduced.

In some embodiments, the minimum width dimension of the tip part 411 is greater than 0.2 μm. Since the tip part 411 is tapered away from the light-emitting direction, the minimum width dimension d thereof is a dimension embedded in the bottom of the pixel defining layer 2.

In some embodiments, as shown in FIG. 6, the pixel unit U includes a first sub-pixel R, a second sub-pixel G and a third sub-pixel B with different colors. In Step S6, evaporating the light-emitting functional layer 3 and the encapsulation layer 5 on the pixel defining layer 2 and the boundary isolation layer 4 includes:

Step S61: evaporating the whole first color light-emitting layer on the pixel defining layer 2 and the boundary isolation layer 4, wherein the first color light-emitting layer is, for example, a red light-emitting layer;

Step S62: forming the whole encapsulation layer 5 on the first color light-emitting layer;

Step S63: removing a light-emitting layer and the encapsulation layer 5 except the first sub-pixel R with the first color by photoetching;

Step S64: evaporating the whole second color light-emitting layer on the pixel defining layer 2 and the boundary isolation layer 4, wherein the second color light-emitting layer is, for example, a green light-emitting layer;

Step S65: forming the whole encapsulation layer 5 on the second color light-emitting layer;

Step S66: removing the light-emitting layer and the encapsulation layer 5 except the second sub-pixel G with the second color by photoetching;

Step S67: evaporating the whole third color light-emitting layer on the pixel defining layer 2 and the boundary isolation layer 4, wherein the third color light-emitting layer is, for example, a blue light-emitting layer;

Step S68: forming the whole encapsulation layer 5 on the third color light-emitting layer; and

Step S69: removing the light-emitting layer and the encapsulation layer 5 except the third sub-pixel B with the third color by photoetching.

According to the manufacturing method of a display panel provided by an embodiment of the present disclosure, by embedding the conductive part 41 of the boundary isolation layer 4 into the pixel defining layer 2, water and oxygen can be prevented from infiltrating from the pixel defining layer 2 into the light-emitting functional layer 3 during the manufacturing process, which can reduce cathode signal transmission resistance and eliminate device crosstalk between light-emitting sub-pixels, and meanwhile can reduce water vapor infiltration in a photoetching process and improve a product yield.

It should be readily understood that the terms “on”, “upon” and “above” in the disclosure should be interpreted in a broadest manner such that “on” not only means “directly on something”, but also means “above something” and there is an intermediate feature or layer, and “upon” or “above” not only means “upon something” or “above something”, but also means “upon something” or “above something” and there is no intermediate feature or layer (i.e., directly on something).

The term “substrate” used herein refers to a material on which a subsequent material layer is added. The substrate itself can be patterned. The material added on the substrate may be patterned or remain unpatterned. In addition, the substrate may include a wide range of materials, such as silicon, germanium, gallium arsenide, and indium phosphide. Alternatively, the substrate may be made of a non-conductive material (such as glass, plastic, or sapphire wafer).

The term “layer” used herein may refer to a material part that includes an area having a certain thickness. The layer may extend over the whole underlying structure or overlying structure or may have an extent smaller than an extent of the underlying or overlying structure. In addition, the layer may be an area of a homogeneous or non-homogeneous continuous structure having a thickness smaller than a thickness of the continuous structure. For example, the layer may be located between top and bottom surfaces of the continuous structure or between any pair of lateral planes at the top and bottom surfaces. The layer may extend laterally, vertically, and/or along a tapered surface. The array substrate may be a layer, may include one or more layers, and/or may have one or more layers thereon, thereabove and/or therebelow. A layer may include a plurality of layers. For example, an interconnected layer may include one or more conductors and contact layers (in which contacts, interconnecting lines, and/or vias are formed) as well as one or more dielectric layers.

At last, it should be noted that: the above embodiments are only used to describe the technical solutions of the present disclosure rather than limiting them; although the present disclosure has been described in detail with reference to the foregoing embodiments, a person skilled in the art in the art should understand that: modifications can still be made to the technical solutions described in the foregoing embodiments, or equivalent substitutions can be made to part or all of the technical features; these modifications or substitutions do not cause the spirit of the corresponding technical solutions to depart from the scope of the technical solutions of the embodiments of the present disclosure.

What is claimed is:

1. A display panel comprising a plurality of pixel units arranged in an array, the pixel unit comprising a plurality of sub-pixels, the display panel comprising an array substrate, and a pixel defining layer, a light-emitting functional layer and an encapsulation layer sequentially formed on the array substrate, in which the array substrate is formed with a plurality of first electrodes arranged in an array, and the pixel defining layer comprises a plurality of pixel openings which expose at least part of the first electrode; the light-emitting functional layer comprises a light-emitting structure on the first electrode and a second electrode layer on the light-emitting structure, wherein
the display panel further comprises a boundary isolation layer located on a side of the pixel defining layer away from the array substrate, the second electrode layer corresponding to two adjacent sub-pixels is disconnected at an edge of the boundary isolation layer, the boundary isolation layer comprises a conductive part and a shielding part located on a side of the conductive part away from the array substrate, and an orthographic projection of the shielding part on the array substrate covers an orthographic projection of the conductive part on the array substrate; and
an end of the conductive part away from the shielding part is embedded in the pixel defining layer to prevent water and oxygen from infiltrating from the pixel defining layer into the light-emitting functional layer.

2. The display panel of claim 1, wherein the conductive part comprises a tip part and a support part which are sequentially arranged along a light-emitting direction, the tip part is embedded in the pixel defining layer, and the support part is located between the tip part and the shielding part; the tip part is tapered away from the light-emitting direction, and the support part is tapered along the light-emitting direction.

3. The display panel of claim 2, wherein a minimum width dimension of the tip part is greater than 0.2 μm, a total thickness of the conductive part is 2 μm to 4 μm, and a thickness of the support part is 0.8 μm to 1.5 μm.

4. The display panel of claim 1, wherein the pixel defining layer is correspondingly provided with a groove that accommodates the conductive part.

5. The display panel of claim 1, wherein the conductive part is produced by printing.

6. The display panel of claim 1, wherein a material of the shielding part is an inorganic silicon-containing material.

7. The display panel of claim 1, wherein a material of the conductive part comprises any one of nano silver paste, nano copper conductive ink and conductive aluminum paste.

8. The display panel of claim 1, wherein the boundary isolation layer is provided on at least one of the sub-pixels in at least one of the pixel units.

9. The display panel of claim 1, wherein the encapsulation layer comprises a first inorganic layer, an organic layer and a second inorganic layer that are sequentially arranged in a direction away from the array substrate, in which the first inorganic layer and the second inorganic layer cover the light-emitting functional layer and the boundary isolation layer, and the organic layer has high elasticity and is sandwiched between the first inorganic layer and the second inorganic layer.

10. A manufacturing method of a display panel, comprising:
providing an array substrate formed with a plurality of first electrodes arranged in an array;
forming a patterned pixel defining layer on the array substrate, wherein the pixel defining layer comprises a plurality of pixel openings and a plurality of grooves, and the pixel opening exposes at least part of the first electrode;
printing a whole conductive layer on the pixel defining layer, wherein the conductive layer covers a plurality of the pixel openings and a plurality of the grooves;
forming a whole shielding layer on the conductive layer;
patterning the shielding layer and the conductive layer by photoetching to form a boundary isolation layer, wherein the boundary isolation layer comprises a conductive part and a shielding part located on a side of the conductive part away from the array substrate, an orthographic projection of the shielding part on the array substrate covers an orthographic projection of the conductive part on the array substrate, and an end of the conductive part away from the shielding part is embedded in the groove of the pixel defining layer; and
forming a light-emitting functional layer and an encapsulation layer on the pixel defining layer and the boundary isolation layer, wherein the light-emitting functional layer comprises a light-emitting structure on the first electrode and a second electrode layer on the light-emitting structure, the second electrode layer corresponding to two adjacent sub-pixels is disconnected at an edge of the boundary isolation layer, and the conductive part is configured to prevent water and oxygen from infiltrating from the pixel defining layer into the light-emitting functional layer.

11. The manufacturing method of claim 10, wherein the display panel comprises a display area and a frame area located on a periphery of the display area, and printing the whole conductive layer on the pixel defining layer comprises:
printing the whole conductive layer corresponding to the display area on the pixel defining layer.

12. The manufacturing method of claim 10, wherein the conductive part comprises a tip part and a support part which are sequentially arranged along a light-emitting direction, the tip part is embedded in the pixel defining layer, and the support part is located between the tip part and the shielding part; the tip part is tapered away from the light-emitting direction, and the support part is tapered along the light-emitting direction.

13. The manufacturing method of claim 12, wherein a minimum width dimension of the tip part is greater than 0.2 μm, a total thickness of the conductive part is 2 μm to 4 μm, and a thickness of the support part is 0.8 μm to 1.5 μm.

14. The manufacturing method of claim 10, wherein the pixel unit comprises a first sub-pixel, a second sub-pixel and a third sub-pixel with different colors, and forming the light-emitting functional layer and the encapsulation layer on the pixel defining layer and the boundary isolation layer comprises:
evaporating a whole first color light-emitting layer on the pixel defining layer and the boundary isolation layer;
forming a whole encapsulation layer on the first color light-emitting layer;
removing a light-emitting layer and the encapsulation layer except the first sub-pixel with the first color by photoetching;
evaporating a whole second color light-emitting layer on the pixel defining layer and the boundary isolation layer;
forming a whole encapsulation layer on the second color light-emitting layer;
removing a light-emitting layer and the encapsulation layer except the second sub-pixel with the second color by photoetching;
evaporating a whole third color light-emitting layer on the pixel defining layer and the boundary isolation layer;
forming a whole encapsulation layer on the third color light-emitting layer; and
removing a light-emitting layer and the encapsulation layer except the third sub-pixel with the third color by photoetching.
